(19) United States
(12) Patent Application Publication
(10) Pub. No.: US 2016/0378366 A1
(43) Pub. Date: Dec. 29, 2016

(54) INTERNAL CONSECUTIVE ROW ACCESS FOR LONG BURST LENGTH

(71) Applicant: Intel Corporation, Santa Clara, CA (US)

(72) Inventors: Shigeki Tomishima, Portland, OR (US); Shih-Lien L. Lu, Portland, OR (US); Kuljit S Bains, Olympia, WA (US)

(21) Appl. No.: 14/749,605

(22) Filed: Jun. 24, 2015

(51) Int. Cl. G06F 3/06; G11C 15/00; G11C 7/10

(52) U.S. Cl. CPC G06F 3/0619; G11C 7/1072; G11C 15/00; G06F 3/0659; G06F 3/0685

(57) ABSTRACT

A memory device executes internal operations to provide a programmable burst length. The memory device includes multiple banks that are independent and separately addressable. The memory device selects a number of banks to operate in burst sequence, where all selected banks operate on a command sent from an associated memory controller. In response to receiving the access command, the memory device generates multiple internal operations to cause all selected memory banks to execute the access command, without requiring multiple commands from the memory controller.

### FIELD

Embodiments of the invention are generally related to memory devices, and more particularly to a memory device with internal burst operation.

### COPYRIGHT NOTICE/PERMISSION

Portions of the disclosure of this patent document may contain material that is subject to copyright protection. The copyright owner has no objection to the reproduction of the patent document or the patent disclosure as it appears in the Patent and Trademark Office patent file or records, but otherwise reserves all copyright rights whatsoever. The copyright notice applies to all data as described below, and in the accompanying drawings hereto, as well as to any software described below: Copyright© 2015, Intel Corporation, All Rights Reserved.

### BACKGROUND

Memory is ubiquitous in computing devices, from the smallest embedded systems to the most powerful servers. Different types of memory have different applications, based on speed, capacity, performance, and other factors. Commodity DRAMs (dynamic random access memory devices) are memory devices that can be readily substituted for each other from any of a number of different manufacturers, and follow a standard or specification of operation. Commodity DRAMs have good access speeds, low relative cost, and high densities (large memory sizes), and are typically used as memory resources for main system memory in computing systems. Specialty DRAMs can also be made and used for caching applications.

When used as main system memory for a computing device, a DRAM is typically configured to fetch certain amounts of data for Read operations and send the data in bursts of multiple consecutive output I/O (input/output) transactions. Similarly for Write operations, the DRAM is typically configured to receive a burst of multiple consecutive input I/O transactions to write to the storage media. A “burst” operation typically involves activating a row and sending multiple consecutive column addresses while the row is activated. Such burst operation makes sense for main memory because of higher data locality, where data is typically accessed in consecutive chunks from contiguous address space. See the description below with respect to FIG. 1.

Thus, many DRAM applications employ an open page policy, where a page or row of data is kept open between consecutive transactions. If the next transaction is to the same row of data, it will already be open, and a column operation (e.g., CAS or column address strobe) is all that is needed to access the next desired memory segment. If the next transaction is to a different row of data, there will be a page fault, and the previous row will need to be discharged and the new row opened prior to access. When there is high data locality, there are fewer page faults, and the performance penalty of a fault is more than offset by the performance efficiencies of not having to open the row on each transaction when there is not a page fault.

However, there tends to be more random access to a cache than to a main memory resource. Thus, in certain applications of DRAMs as cache resources, consecutive transactions are less frequently directed to the same row in a cache as compared to main memory access. In applications with higher random access, DRAMs are typically managed with a close page policy (also referred to as a closed page policy). In a close page policy, a row is closed after access. In reality, most modern close page policies use custom, hybrid approaches where a row is left open for a period of time (e.g., as governed by a timer), and closed after a threshold period of time. Hybrid approaches can be considered essentially close page policies for purposes herein.

In any close page policy, there is traditionally a limit to how much data can be written or read in a given transaction (e.g., operations related to executing a single access command). Such applications are different from typical open page policies where there is a configured burst length (BL). However, even in applications with higher random access where close page policies offer better overall performance, there are times that being able to perform access in a burst would provide better performance.

Referring now to FIG. 1, diagram 100 illustrates timing diagram of a prior art read command. Diagram 100 illustrates relative timing for various signal lines; namely, the clock signal (CLK), the command signal (CMD), the address signal (ADDR), the data strobe and strobe complement (respectively, DQS and DQS# (the dashed line)), and the data signal (DQ). The CLK is shown from a time TO when an initial Read command is issued on the CMD line, until time T13 when the data for a second Read command finishes sending. The first Read command is accompanied by an address of Bank and Column n at time TO, and a second Read command is accompanied by an address of Bank and Column b at time T4. As shown on the ADDR line, the time between read commands is tCCD, which is a minimum column-to-column address timing. tRPST time of read postamble.

As seen on the DQS line, the memory device has a time of tRPRE as a Read preamble to settle the strobe line prior to the burst data for the first Read command. After the preamble time, the DQ line shows a burst of eight portions of data, DQn to DQ(n+7). It will be understood that the memory device is configured to fetch and output a burst of 8 bits of data from the bank. Traditionally, the prefetch and output are based on a single transaction within the bank in response to the first external Read memory access command. A second burst of 8 bits of data is output starting at column b (so data DQb to DQ(b+7)) in response to the second external Read access command. As seen on the strobe line, the last bit of data can also coincide with a Read postamble time tRPST to settle the strobe line after the output transactions. The data bursts traditionally occur in response to a command, and operate on a specified bank based on the internal prefetch mechanism of the memory device.

### BRIEF DESCRIPTION OF THE DRAWINGS

The following description includes discussion of figures having illustrations given by way of example of implementations of embodiments of the invention. The drawings should be understood by way of example, and not by way of limitation. As used herein, references to one or more “embodiments” are to be understood as describing a particular feature, structure, and/or characteristic included in at least one implementation of the invention. Thus, phrases such as “in one embodiment” or “in an alternate embodiment” appearing herein describe various embodiments and implementations of the invention, and do not necessarily all refer to the same embodiment. However, they are also not necessarily mutually exclusive.

FIG. 1 is a timing diagram of a prior art read command.

FIG. 2 is a block diagram of an embodiment of a system with a memory device that has internal burst control.

FIG. 3 is a block diagram of an embodiment of a memory device that provides internal burst control.

FIG. 4 is a block diagram of an embodiment of a memory device with control logic that performs internal burst control.

FIG. 5A is a timing diagram of an embodiment of internal burst control in a memory device.

FIG. 5B is a timing diagram of an embodiment for a read from a memory device having internal burst control.

FIG. 6 is a flow diagram of an embodiment of a process for accessing a memory device that has internal burst control.

FIG. 7 is a block diagram of an embodiment of a computing system in which memory device internal burst control can be implemented.

FIG. 8 is a block diagram of an embodiment of a mobile device in which memory device internal burst control can be implemented.

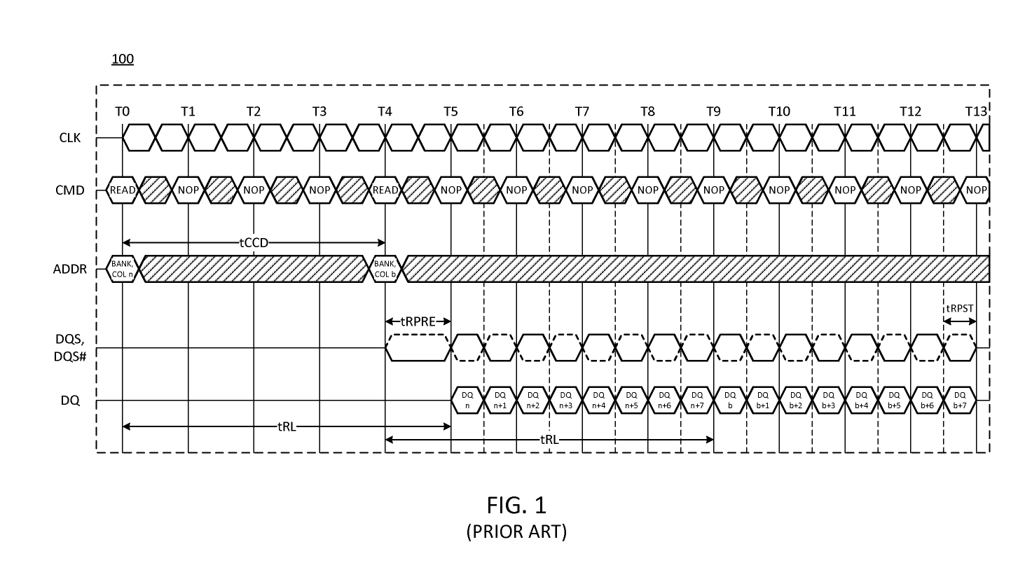

Descriptions of certain details and implementations follow, including a description of the figures, which may depict some or all of the embodiments described below, as well as discussing other potential embodiments or implementations of the inventive concepts presented herein.

### DETAILED DESCRIPTION

As described herein, a memory device executes internal operations to provide a programmable burst length. The memory device includes multiple banks that are independent and separately addressable. The memory device selects a number of banks or bank groups to operate in burst sequence, where all selected banks or bank groups operate on a command sent from an associated memory controller, based on internal operations generated by the memory device. A bank group is one or more banks that that can be separately addressed and accessed; thus, banks in different bank groups can be considered independent from each other, and an access command to banks in different bank groups can be executed in parallel. Typically a memory device includes logic to allow separate access to banks and bank groups. Reference herein to selecting bank groups and accessing bank groups will be understood to apply to any one or more banks that are independently addressable (such as by having different groups have different addresses). Thus, use of “bank group” herein is not limiting. In response to receiving the access command, the memory device generates multiple internal operations to cause all selected bank groups to execute the access command, without requiring multiple commands from the memory controller. Thus, the memory device can provide programmable burst operation even when operated in a close page policy.

Reference to memory devices can apply to different memory types. Memory devices generally refer to volatile memory technologies. Volatile memory is memory whose state (and therefore the data stored on it) is indeterminate if power is interrupted to the device. Nonvolatile memory or storage holds its state even if power is interrupted (subject to degradation over long periods of time). Dynamic volatile memory requires refreshing the data stored in the device to maintain state. One example of dynamic volatile memory includes DRAM (dynamic random access memory), or some variant such as synchronous DRAM (SDRAM). A memory subsystem as described herein may be compatible with a number of memory technologies, such as DDR3 (dual data rate version 3, original release by JEDEC (Joint Electronic Device Engineering Council) on Jun. 27, 2007, currently on release 21), DDR4 (DDR version 4, initial specification published in September 2012 by JEDEC), LPDDR3 (low power DDR version 3, JESD209-3B, August 2013 by JEDEC), LPDDR4 (LOW POWER DOUBLE DATA RATE (LPDDR) version 4, JESD209-4, originally published by JEDEC in August 2014), WIO2 (Wide I/O 2 (WideIO2), JESD229-2, originally published by JEDEC in August 2014), HBM DRAM (HIGH BANDWIDTH MEMORY, JESD235, originally published by JEDEC in October 2013), and/or others, and technologies based on derivatives or extensions of such specifications.

In addition to, or alternatively to, volatile memory, in one embodiment, reference to memory devices can refer to a nonvolatile memory device whose state is determinate even if power is interrupted to the device. In one embodiment, the nonvolatile memory device is a block addressable memory device, such as NAND or NOR technologies. Thus, a memory device can also include a future generation nonvolatile devices, such as a three dimensional crosspoint memory device, or other byte addressable nonvolatile memory devices. In one embodiment, the memory device can be or include multi-threshold level NAND flash memory, NOR flash memory, single or multi-level Phase Change Memory (PCM), a resistive memory, nanowire memory, ferroelectric transistor random access memory (FeTRAM), magnetoresistive random access memory (MRAM) memory that incorporates memristor technology, or spin transfer torque (STT)-M RAM, or a combination of any of the above, or other memory.

Descriptions herein referring to a “DRAM” will be understood to apply to any memory device that allows random access. The memory device or DRAM can refer to the die itself and/or to a packaged memory product. The DRAMs include multiple banks that can be managed as separate bank groups.

In specialty DRAM designs, the DRAM can be used as a last level cache or near memory device. In such designs, the memory subsystem manages the DRAM with shorter page sizes as compared to typical main memory applications of a DRAM. Additionally, the memory array (storage media) on the DRAM typically has more bank groups to achieve lower power, shorter latency, and higher effective bandwidth having fewer conflicts due to being able to separately address more independent areas of the memory device. As referred to above, such applications of DRAM typically employ close page policy to have better response to random accesses.

As described herein, the burst control or internal consecutive row access control within the DRAM can provide burst access, allowing consecutive accesses similar to what is provided by the burst mode in a standard DRAM application. Thus, a specialty DRAM in a caching application can provide burst access. Providing burst control can reduce command traffic and reduce the command/address power consumption due to using less I/O (input/output). In one embodiment, a commodity DRAM provides burst control. In one embodiment, other memory technologies such as SRAM, STTM (STT-M RAM), FeDRAM, or others can similarly apply burst control internally at the memory device.

In one embodiment, a memory controller determines when to apply burst access for an access command. In one embodiment, the memory controller sets a mode register or other mechanism within the DRAM that configures the settings of how the DRAM will operate. The burst length (BL) can be adjustable and dynamically programmable or configurable. Thus, the DRAM can be dynamically configured to provide different amounts of data on Read transactions or receive different amounts of data on Write transactions, based on the BL setting. In one embodiment, the memory controller can configure the DRAM BL setting based on defining one or more additional commands in a protocol. The additional commands can be in addition to or alternative to the use of a mode register. Additional commands may require additional pins on a command interface between the DRAM and the memory controller. Additional commands could allow the DRAM to be configured once in a mode register setting for variable burst length, and then change the BL on the fly with the additional commands.

As described herein, in one embodiment, the memory controller does not need to send multiple access commands to achieve a longer burst length. Rather, the DRAM itself can generate multiple internal operations to execute in response to a single access command from the memory controller. It will be understood that a “single” access command can refer to an access command sequence, meaning a sequence of multiple different commands that trigger a single access transaction. For example, DRAMs typically have an Activate (ACT) command followed by a column command (CAS—column address strobe), where the column command can be specific to Read (RD) or Write (WR). Thus, the memory controller can send a sequence of ACT and then RD-CAS or ACT and then WR-CAS to execute a Read transaction or a Write transaction, respectively. In response to the single command or command sequence, DRAM can generate and perform multiple internal operations for different bank groups. Such a transaction can achieve a longer BL based on a single transaction command overhead. In one embodiment, the single command can be an Activate command, a column address command, and a Precharge (PRE) command.

In one embodiment, the DRAM includes an internal counter to enable the DRAM itself to control the order of access to the banks or bank groups. In one embodiment, the DRAM accesses the bank groups in a fixed sequence, such as in address order. In one embodiment, the fixed sequence is a specific, preset order of access for the bank groups that is not in address order. In one embodiment, the sequence is not fixed, and an internal DRAM controller manages access to the bank groups based on one or more counters that indicate which bank groups have been accessed within a cycle. Thus, the DRAM can internally manage interleaving of access to its bank groups.

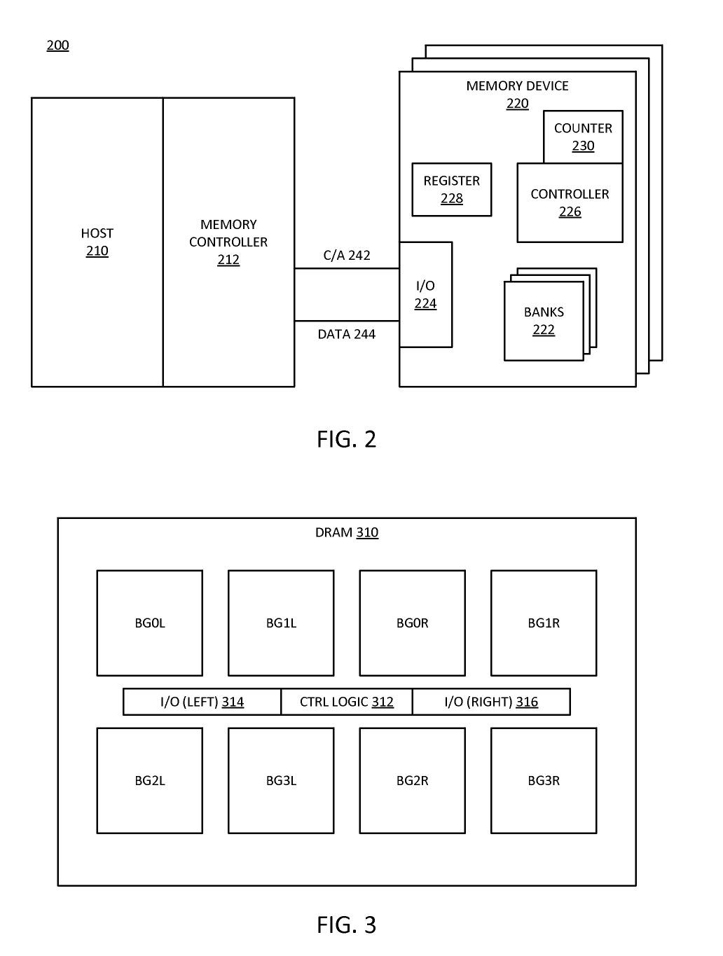

FIG. 2 is a block diagram of an embodiment of a system with a memory device that has internal burst control. System 200 represents a memory subsystem that can be implemented in a mobile device. Host 210 represents a host computing platform that executes an operating system (OS) and applications. The OS and applications execute operations that result in memory accesses. Host 210 includes a processor or processing unit, which can be a single or multicore processor. System 200 can be implemented as an SOC, or be implemented with standalone components. When multiple memory devices 220 are included in system 200, each memory device can individually manage the generation of internal operations to execute commands from memory controller 212.

Memory controller 212 represents control logic that generates memory access commands in response to the execution of operations by the processor(s). In one embodiment, memory controller 212 is part of host 210, such as logic implemented on the same die or package space as a host processor. In one embodiment, memory device 220 is a DRAM last level cache (such as an L3 cache) in system 200. In one embodiment, memory device 220 implements a close page policy.

Memory devices 220 represent memory resources for system 200, and can be referred to as DRAMs. Memory devices 220 each include multiple memory banks 222. Banks 222 represent the storage media where memory device 220 stores data. Banks 222 can be organized as bank groups. A bank of memory is a group of memory cells that can be accessed independent of other groups of memory cells. A bank group is one or more banks that are operated independently of other banks. Banks from different bank groups can be accessed in parallel. It will be understood that parallel access occurs in sequence when true parallel operation is not supported within the memory devices. However, even sequential operation can appear to be parallel from an external connection when the resulting access does not result in access delays between the banks. Reference herein to selecting bank groups and accessing bank groups will be understood to apply to any one or more banks 222 that are independently addressable (such as by having different groups have different addresses).

Memory device 220 includes I/O (input/output) hardware 224 to connect to memory controller 212 via one or more buses. I/O 224 can include drivers, latches, termination, and/or other hardware. In one embodiment, the interface between memory controller 212 and I/O 224 can include C/A (command/address) bus 242 and data bus 244. C/A bus 242 enables memory controller 212 to send command and address information to memory device 220. Data bus 244 enables memory controller 212 to send data for Write transactions, and for memory device 220 to send data for Read transactions.

Controller 226 represents control logic on memory device 220, and can be implemented as a microcontroller or microprocessor on-chip. Controller 226 manages operations within memory device 220. Controller 226 manages the timing of execution within memory device 220 to execute commands sent by memory controller 212. In one embodiment, controller 226 generates multiple internal transactions to execute a single command transaction sent by memory controller 212.

In one embodiment, system 200 is incorporated into a computing system that needs to reduce memory command traffic, to reduce memory subsystem power consumption, and/or to fill a cacheline with simple transactions. By configuring memory device 220 (e.g., by configuration of controller 226) for burst operation, system 200 can provide the desired benefits. Such benefits can be achieved even in an application with specialty DRAMs with close page policy and small page size.

In one embodiment, memory controller 212 can configure memory device 220 for burst operation based on programming a setting in register 228. Register 228 represents a mode register or other setting storage for memory device 220. Thus, burst operation can be selectively turned on an off. In one embodiment. BL for memory device 220 can be programmed to be one of multiple different settings (e.g., 4 or 8). In one embodiment, burst operation can be programmed to start from a specified bank group (BG) address identified in a command from memory controller 212. In one embodiment, burst operation can be programmed to always start at BG address 0, or another address. Register 228 can store such starting address settings. Controller 226 manages the implementation of the burst control or consecutive row access based on settings in register 228 and/or other settings.

In one embodiment, memory device 220 includes counter 230. In one embodiment, counter 230 is part of controller 226. Counter 230 can generate BG addresses with a fixed delay (e.g., 1 ns delay). With counter 230, controller 226 would not need memory controller 212 to generate the bank group address information for commands. Alternatively, controller 226 could ignore BG address information received from memory controller 212. In one embodiment, controller 226 uses counter data to monitor bank group operation. Monitoring bank group operation can include monitoring the sequence of operations through the bank groups, to make sure that each bank group is accessed in turn through a cycle. The cycle can specify that every bank group is accessed once before another bank group is accessed a second time. With counter 230, controller 226 can sequence operations through banks 222 in order of address of the banks/bank groups and/or can sequence operations through in an interleaved manner that is not in sequential address order.

In one embodiment, an interface protocol between memory controller 212 and memory device 220 supports additional specification commands to change the BL and/or burst ordering on the fly. On the fly operation refers to changing a configuration of operation of the memory device without changing a register setting. A register setting or other configuration setting can be set to enable on the fly operation, but then on the fly operation can occur at runtime without needing to further adjust configuration of the memory device.

In one embodiment, memory controller 212 monitors access behavior for efficiency. For example, the memory controller can count how many transactions follow a burst pattern, and would therefore benefit from burst access to memory device 220. Based on the monitored information, the memory controller can compute a BL that would result in higher access efficiency. When memory device 220 is enabled for burst operation, a single command sequence, such as ACT, CAS, and PRE from memory controller 212 can result in cycling of the same operations through multiple bank groups.

FIG. 3 is a block diagram of an embodiment of a memory device that provides internal burst control. DRAM 310 illustrates one example of an embodiment of a memory device in accordance with any DRAM described herein. DRAM 310 is one example of memory device 220 of FIG. 2. In one embodiment, DRAM 310 is a specialty DRAM with additional bank groups as compared to a commodity DRAM design. In one embodiment, additional bank groups are provided by including additional logic (e.g., routing, signaling, interface) to access the memory resources in independent groups. As illustrated, DRAM 310 includes bank groups that are organized as “Left” and “Right” bank groups, as well as “upper” and “lower” bank groups. It will be understood that orientation labels such as left, right, upper, and lower, are relative and do not limit the operation of the device. Typically such orientation is made in reference to a specified pinout for a packaged DRAM device. The labels in reference to FIG. 3 are examples only, and are not limiting. Furthermore, the example of DRAM 310 in FIG. 3 has I/O and control logic in the center of die, as described in more detail below. Such a configuration is only one example, and is not limiting. The techniques for performing internal operations to increase a burst length can also be applied to DRAMs having I/O at the left and right die edges, such as in LPDDR DRAMs.

The upper bank groups include left bank groups BG0L and BG1L as well as right bank groups BG0R and BG1R. The lower bank groups include left bank groups BG2L and BG3L as well as right bank groups BG2R and BG3R. The center of the DRAM (e.g., the center of a die implementation of DRAM 310) can include I/O pads and control logic. In one embodiment, I/O 314 provides I/O for left banks BG[0:3]L and I/O 316 provides I/O for right banks BG[0:3]R. In a packaged implementation, I/O 314 and 316 will be connected to pins on the interface packaging. In an SoC (system on a chip) implementation, there can be chip level interconnecting such as flip-chip connections, or bonding wires. In a typical example, DRAM 310 could include a total of ×64 I/O, split as two groups of ×32 (left and right). I/O 314 and I/O 316 can include hardware such as drivers and other interface circuitry to connect to the various bank groups. In one embodiment, control logic 312 includes management logic that controls operations within DRAM 310.

In one embodiment, DRAM 310 is implemented with a close page policy to increase the potential of the random access flexibility. In one embodiment, DRAM 310 provides one channel on each side: the left side being one channel and the right side being a different channel. Thus, DRAM 310 can include 4 bank groups each on two separate channels. In one embodiment, commands from an associated memory controller (not shown) can be received and processed by control logic 312. In one embodiment in response to a single RD command, DRAM 310 internally, sequentially generates multiple internal operations to execute the RD command at each bank group (for the channel receiving the command). In one embodiment, control logic 312 includes a BG counter to generate consecutive BG addresses, to access each BG internally and sequentially in response to the command. In one embodiment, each BG has only 2N of prefetech data (where N is the number of address bits used), and DRAM 310 can generate a burst equal to the number of selected bank groups times 2N. For example, DRAM 310 can be configured to generate 8 bits of output data in a burst. In one embodiment, DRAM 310 can access each different BG with 1 ns latency. Thus, consider a RD command received at DRAM 310: control logic 312 can consecutively issue the RD command to different BGs with 1 ns command latency, and generate read-out data with DDR (Double Data Rate) seamlessly with a 1 GHz clock frequency.

In one embodiment, DRAM 310 is a DDR ×4 device. It will be understood that a ‘×4’ device refers to a DRAM having a 4-bit wide data interface. Alternatives include a ×8 device (an 8-bit wide data interface), a ×16 device (a 16-bit wide data interface), and so on. A commodity DRAM can have a page size of 8Kb or larger with a data transfer width between the page (the row of memory cells) and the chip interface peripheral circuits (e.g., read/write I/O buffer) of only 32 bits. Thus, burst operation in a commodity implementation is reasonable to utilize the large page size. In one embodiment, DRAM 310 has a smaller page size than commodity DRAM, such as a 64B, 128B, 256B, or other length page size or line size. Smaller page size can lower power consumption due to activation, while increasing the access speed due to lower capacitive load. Smaller page size is also more efficient for more random access.

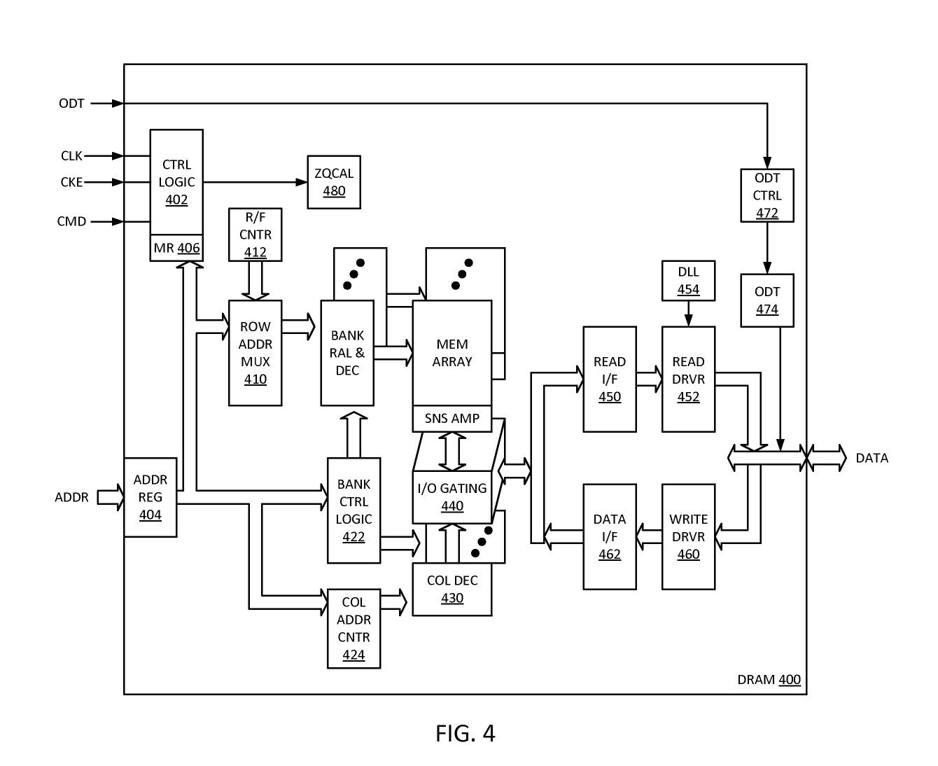

FIG. 4 is a block diagram of an embodiment of a memory device with control logic that performs internal burst control. DRAM 400 represents one example of a memory device in accordance with any system described herein that can use a DRAM with internal burst control. Control logic 402 represents a controller or control logic within the memory device in accordance with any embodiment described herein. Control logic 402 receives clock (CLK), clock enable (CKE), and command (CMD) signals, and controls the operation of DRAM 400 in accordance with those signals. Control logic 402 can operate based on setting stored in mode register (MR) 406. In one embodiment, control logic 402 provides control over memory banks in different bank groups, and generates multiple internal operations in response to a single command from the memory controller or host.

Address register 404 receives address information (ADDR) such as row address and bank address signals to identify the portion of memory to be affected by a particular command. Address register 404 distributes the address information to row address multiplexer 410, bank control logic 422, column address counter 424, and mode register 406. Row address mux 410 takes the row address information and a signal from refresh counter 412 as input, and controls the row address latch (RAL) and decoder for each bank group. The logic can be connected to multiple banks that make up the bank group. Bank control logic 422 selects which bank group will be selected for the memory access operation (command) received. Column address counter 424 generates a signal to select the column for the operation. In one embodiment, control logic 402 includes a counter (not explicitly shown) to internally generate bank group addresses and sequence through selected bank groups for a single command. Thus, one or more selected bank groups can operate on a single command.

The RAL and decoder for the bank groups selects an address in the memory array(s) of the banks/bank groups, and the sense amplifiers can be activated, depending on the operation. I/O gating 440 can place data into the sense amplifiers for a write operation, and can read the data out for a read operation. Column decoder 430 receives the bank control logic selection and the column address counter selection and makes a column selection for I/O gating 440.

Read interface 450 is coupled to receive data bits from I/O gating 440 for a read operation. Read interface 450 can include a read latch and mux, and feeds selected output data into read driver 452, which will place the data on the signal lines of the data bus (DATA). The timing for driving the data bus is provided by DLL 454, which is controlled by control logic 402. Driver 452 can drive data strobe lines based on the timing to accompany the data signals. Write receiver 460 receives write data from the data bus, and inputs it into an input register or input buffer of the write data interface 462. Data interface 462 can provide the data to I/O gating 440.

In one embodiment, DRAM 400 includes ZQCal 480 to provide impedance calibration functions with respect to data on the data bus. In one embodiment, DRAM 400 includes ODT (on die termination) control 472 to control input and/or output impedance circuits applied to the I/O to the data bus. ODT 474 represents the impedance circuits that can be applied in accordance with a configuration setting for impedance for DRAM 400 on a given transaction.

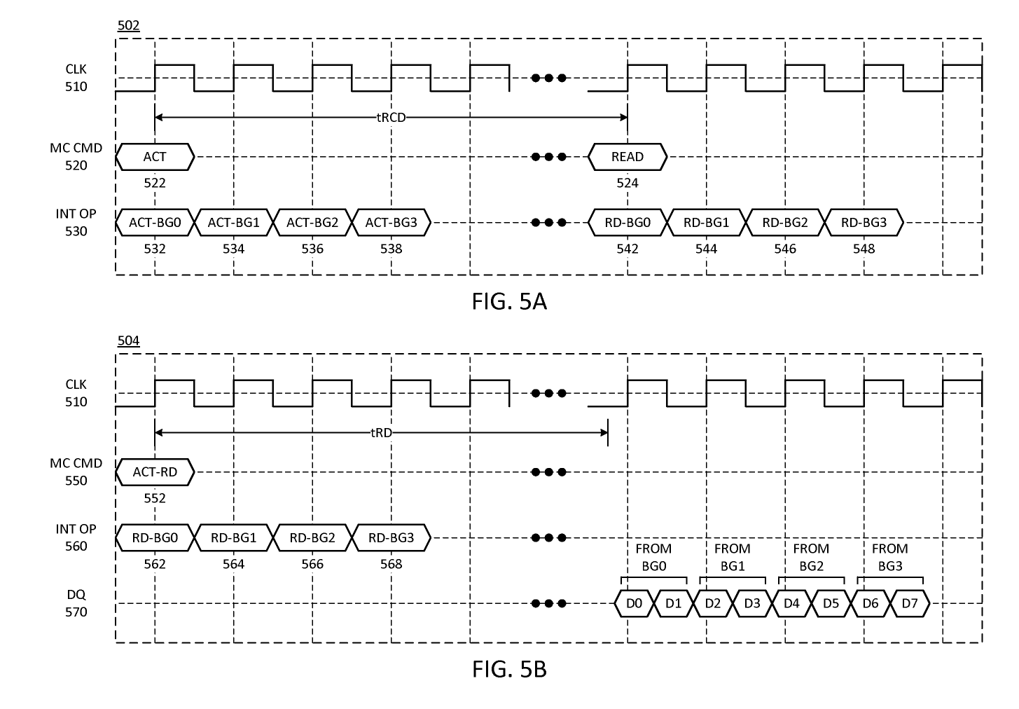

FIG. 5A is a timing diagram of an embodiment of internal burst control in a memory device. Diagram 502 illustrates an example of relative timing of signaling for a clock signal (CLK 510), a memory controller command (CMD 520), and an internal operation (INT OP 530). For purpose of readability, diagram 502 includes a grid. It will be understood that the timing of the signal is intended to be shown at a high level, and is not necessarily detail-accurate for an actual implementation.

CLK 510 represents a clock signal used within the memory device. In one embodiment, the memory device receives an activation command, ACT 522, on command line 520 from an associated memory controller. Between ACT 522 and READ 524 there is a delay of tRCD. In one embodiment, READ 524 represents a RD-CAS command, and the sequence of ACT 522 and READ 524 represents a single access command sent by the memory controller. An internal controller of the memory device receives and processes the received commands. While a Read command is illustrated, it will be understood that a Write would look similar to what is shown in diagram 502.

In one embodiment, in response to ACT 522, the memory device (via its controller) generates multiple internal operations. As illustrated, the memory controller generates four internal operations, 532, 534, 536, and 538. It will be understood based on diagram 502 that the memory device is configured to access four bank groups as a burst. The number of bank groups that will be accessed in sequence varies depending on the implementation and the configuration provided to the memory device. Thus, other transactions can be different than what is depicted in diagram 502. It will be observed that internal operation 532 is aligned with ACT 522 for purpose of illustration. In one embodiment, there may be a delay, such as a propagation delay and/or processing delay, between ACT 522 and internal operation 532. The timing of the other internal operations can likewise be offset from what is illustrated.

In one embodiment, operation 532 is an activate command for bank group 0 (ACT-BG0), operation 534 is an activate command for bank group 1 (ACT-BG1), operation 536 is an activate command for bank group 2 (ACT-BG2), and operation 538 is an activate command for bank group 3 (ACT-BG3). While the internal operations illustrated are in address order, it will be understood that the memory device can generate internal operations out of address order. In response to READ 524, the memory device also generates four internal operations: 542, 544, 546, and 548. It will be understood that while the order of the bank groups in internal operation 530 can vary from what is shown, the order of the internal operations generated in response to READ 524 will be the same as the order of internal operations as for ACT 522. In one embodiment, operation 542 is a read command for bank group 0 (RD-BG0), operation 544 is a read command for bank group 1 (RD-BG1), operation 546 is a read command for bank group 2 (RD-BG2), and operation 548 is a read command for bank group 3 (RD-BG3).

Thus, in one embodiment, an ACT command is defined to open multiple (such as four, depending on how many bank groups are selected for the burst operation) pages across bank groups. In one embodiment, the order of sequencing through bank groups and the number of bank groups to sequence through are defined in a mode register. In one embodiment, command encodings are defined to select the sequence of bank groups to give more flexibility to the memory controller. In one embodiment, a Precharge command is also defined in a similar fashion to sequence through multiple bank groups to precharge the selected number of pages. In one embodiment, Read or Write commands with an auto-precharge will also result in cycling through the selected number of bank groups via internal control logic within the memory device.

As illustrated, the memory device generates four internal operations, 532, 534, 536, and 538 in response to receiving ACT 522. Similarly, the memory device generates four corresponding internal operations 542, 544, 546, and 548 in response to READ 524. It will be understood that in one embodiment, the memory device can select a different number of bank groups for a subsequent access transaction. Thus, while four bank groups are selected in the example of diagram 502, a different number of bank groups could be selected. Additionally, the same number of bank groups is not necessarily selected for a subsequent transaction. Rather, the memory device can be configured dynamically for how many bank groups to select. In one embodiment, a memory controller computes a burst length and configures the memory device for that burst length. If activity in the memory controller changes, the memory controller can determine that a different burst length would provide better performance. In one embodiment, the memory controller can change the burst length for the memory device, and the memory device would select a different number of bank groups (e.g., two) on a subsequent transaction from what is illustrated in diagram 502.

FIG. 5B is a timing diagram of an embodiment for a read from a memory device having internal burst control. Diagram 504 is one example of a timing diagram in accordance with diagram 502 of FIG. 5A. Both diagrams 502 and 504 can be examples of timing sequences for internal burst control in accordance with any embodiment described herein. As with diagram 502, diagram 504 illustrates a Read command sequence, but it will be understood that the same principles can be applied to a Write command. Diagram 504 illustrates clock signal CLK 510, a memory controller command MC CMD 550, a memory device internal operation INT OP 560, and a data signal DQ 570. The same clock is illustrated, and thus diagram 504 has the same clock line as diagram 502. The other signals may be the same or different as those in diagram 502, and are thus labeled differently in diagram 504.

In one embodiment, CMD 550 receives a Read command transaction, which can include an ACT command and a RD command, illustrated together as ACT-RD 552. It will be understood that ACT-RD 552 represents a single Read command transaction, whether by single command or a sequence of commands. ACT-RD 552 represents a command that cause an activation and a read of memory, and includes row address and column address information. In one embodiment, the Read transaction includes an ACT command that is not sent separately. The time between receiving the Read command and outputting data is tRD. In one embodiment, the ACT and/or RD commands include row address information for the selected memory cells. The command triggers the memory device to activate the wordline (WL) specified by the row address to select the memory cells. When selected, the cell data can be sensed and latched as the sense amplifiers (SAs), such as what is illustrated in FIG. 3. Traditionally, the page size is a wordline, which can be 4Kb (0.5 KB), 8Kb (1 KB), or 16Kb (2 KB) in a commodity DRAM implementation. It will be understood that different architectures are different, but an access bit count page is typically 32b, 64b, or 128b. Thus, to fill a 512b cacheline for the computing system, traditional memory subsystems have the memory controller implement multiple column operations (e.g., RD-CAS, WR-CAS) multiple times in sequence in a burst operation.

As described herein, the memory device can generate multiple internal commands in response to a single external transaction command. In one embodiment, the memory device generates multiple BG addresses with commands in response to ACT-RD 552. Thus, for example, the memory device can generate RD-BG0 562 as a read command for bank group 0, RD-BG1 564 as a read command for bank group 1, RD-BG2 566 as a read command for bank group 2, and RD-BG3 568 as a read command for bank group 3. Internal operations 562, 564, 566, and 568 represent any one or more internal operations needed to execute a read transaction in the selected bank groups. In one response to the internal operations, each bank group accesses the requested read data. As mentioned above with respect to diagram 502, there can be offsets in the timing between ACT-RD 522 and the internal operations, for example, due to propagation delay and/or processing delay.

As illustrated at DQ 570, BG0 can generate data D0 and D1, BG1 can generate data D2 and D3, BG3 can generate data D4 and D5, and BG3 can generate data D6 and D7. It will be understood that different data outputs are possible depending on how many bank groups are selected for the burst operation. In one embodiment, the memory device generates the internal bank group operations with a command latency of 1 ns, to generate Read operations at each BGs with 1 ns delay seamlessly. Then, at the I/O pin, the memory device can output consecutive data from the different bank groups with DDR. As illustrated in diagram 504, the output sequence is equivalent to a BL=8 in a commodity DRAM.

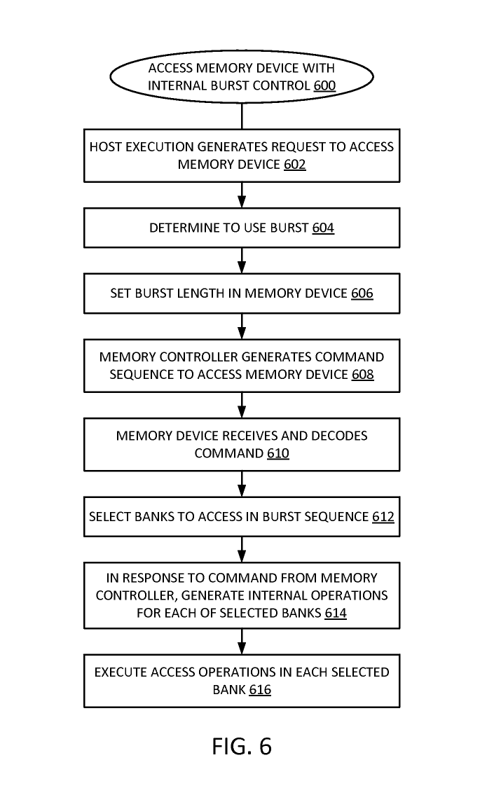

FIG. 6 is a flow diagram of an embodiment of a process 600 for accessing a memory device that has internal burst control. Process 600 can be a process for access in burst mode in accordance with any embodiment described herein. In one embodiment, execution of operations by a host generates a request to access a memory device, 602. The execution can be execution of any service or agent on the computing platform, which can include an operating system component and/or an application component. The host includes a central processor or peripheral processor. The access can be a read or a write to a cache in response to data needed for host execution.

In one embodiment, the memory subsystem determines to use burst operation for access to the memory device, 604. In one embodiment, the memory device is managed with a close page policy, and does not keep pages open for multiple consecutive operations. Even in an open page policy, the ability of the memory device to execute a burst of internal operation (e.g., a “burst mode”) can prevent the memory controller from needing to send additional commands to execute a burst operation. In one embodiment, the memory controller determines to use a burst mode based on monitoring access traffic. In one embodiment, the memory controller sends a mode register setting command or other command to set a burst length in the memory device, 606. Internally, the memory device will select a number of bank groups for execution based on the burst length setting. In a DDR implementation, the number of bank groups to select is the burst length setting divided by two. The burst length, and thus the number of bank groups to select, can be dynamically implemented and configured.

In one embodiment, the memory controller generates a command or command sequence to access the memory device, 608. A single command can include multiple signal parts sent in sequence, or can be a single signal. The single command is the entirety of the command parts for the transaction, which are needed to identify the command requested and the address to access. The memory device receives and decodes the command, 610. The memory device dynamically selects the bank groups to access in the burst sequence, 612.

In response to the command from the memory controller, the memory device internally generates multiple internal operations for each of the selected bank groups, 614. Thus, the memory device can select multiple bank groups to operate on the received command and cause all selected bank groups to execute the received access command, 616. In one embodiment, executing the access operations can include the memory device generating a sequence of operation for the selected bank groups. The order of operation can be in order of bank group address, or some other order. The memory device can include an internal counter for generating the internal operations for the bank groups.

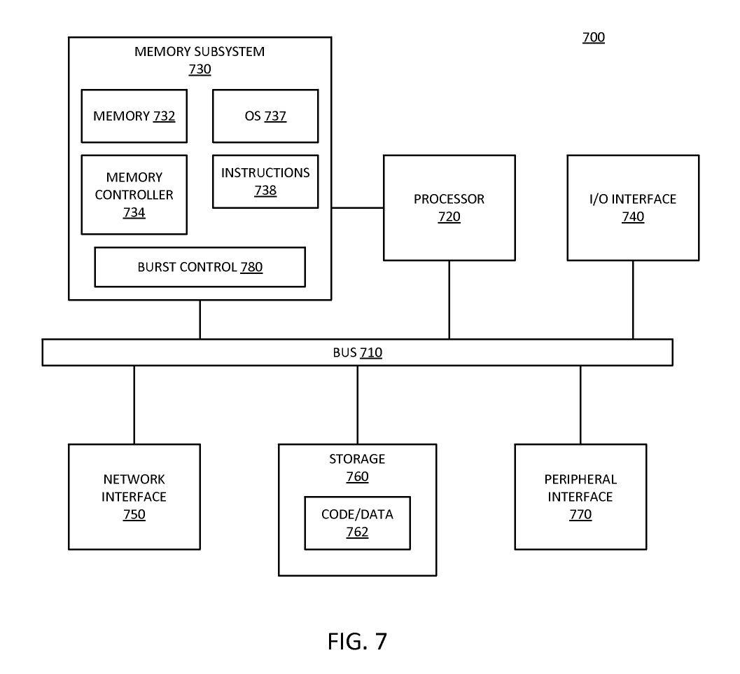

FIG. 7 is a block diagram of an embodiment of a computing system in which memory device internal burst control can be implemented. System 700 represents a computing device in accordance with any embodiment described herein, and can be a laptop computer, a desktop computer, a server, a gaming or entertainment control system, a scanner, copier, printer, routing or switching device, or other electronic device. System 700 includes processor 720, which provides processing, operation management, and execution of instructions for system 700. Processor 720 can include any type of microprocessor, central processing unit (CPU), processing core, or other processing hardware to provide processing for system 700. Processor 720 controls the overall operation of system 700, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

Memory subsystem 730 represents the main memory of system 700, and provides temporary storage for code to be executed by processor 720, or data values to be used in executing a routine. Memory subsystem 730 can include one or more memory devices such as read-only memory (ROM), flash memory, one or more varieties of random access memory (RAM), or other memory devices, or a combination of such devices. Memory subsystem 730 stores and hosts, among other things, operating system (OS) 736 to provide a software platform for execution of instructions in system 700. Additionally, other instructions 738 are stored and executed from memory subsystem 730 to provide the logic and the processing of system 700. OS 736 and instructions 738 are executed by processor 720. Memory subsystem 730 includes memory device 732 where it stores data, instructions, programs, or other items. In one embodiment, memory subsystem includes memory controller 734, which is a memory controller to generate and issue commands to memory device 732. It will be understood that memory controller 734 could be a physical part of processor 720.

Processor 720 and memory subsystem 730 are coupled to bus/bus system 710. Bus 710 is an abstraction that represents any one or more separate physical buses, communication lines/interfaces, and/or point-to-point connections, connected by appropriate bridges, adapters, and/or controllers. Therefore, bus 710 can include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus (commonly referred to as “Firewire”). The buses of bus 710 can also correspond to interfaces in network interface 750.

System 700 also includes one or more input/output (I/O) interface(s) 740, network interface 750, one or more internal mass storage device(s) 760, and peripheral interface 770 coupled to bus 710. I/O interface 740 can include one or more interface components through which a user interacts with system 700 (e.g., video, audio, and/or alphanumeric interfacing). In one embodiment, I/O interface 740 can include a high definition (HD) display that provides an output to a user. High definition can refer to a display having a pixel density of approximately 100 PPI (pixels per inch) or greater, and can include formats such as full HD (e.g., 1080p), retina displays, 4K (ultra high definition or UHD), or others. High definition can also refer to projected displays (e.g., head-mounted displays) that have comparable visual quality to pixel displays. Network interface 750 provides system 700 the ability to communicate with remote devices (e.g., servers, other computing devices) over one or more networks. Network interface 750 can include an Ethernet adapter, wireless interconnection components, USB (universal serial bus), or other wired or wireless standards-based or proprietary interfaces.

Storage 760 can be or include any conventional medium for storing large amounts of data in a nonvolatile manner, such as one or more magnetic, solid state, or optical based disks, or a combination. Storage 760 holds code or instructions and data 762 in a persistent state (i.e., the value is retained despite interruption of power to system 700). Storage 760 can be generically considered to be a “memory,” although memory 730 is the executing or operating memory to provide instructions to processor 720. Whereas storage 760 is nonvolatile, memory 730 can include volatile memory (i.e., the value or state of the data is indeterminate if power is interrupted to system 700).

Peripheral interface 770 can include any hardware interface not specifically mentioned above. Peripherals refer generally to devices that connect dependently to system 700. A dependent connection is one where system 700 provides the software and/or hardware platform on which operation executes, and with which a user interacts.

In one embodiment, system 700 includes burst control 780, which can be logic within memory 732 of memory subsystem 730. Burst control 780 enables memory 732 to generate multiple internal operations in response to a single memory access command transaction from memory controller 734, in accordance with any embodiment described herein. Thus, memory 732 can internally perform operations to extend a burst length of I/O with memory controller 734 without the memory controller needing to send multiple latching commands. In one embodiment, burst control 780 can include an internal bank group counter, and logic to control the sequence of the internal operations. In one embodiment burst control 780 accesses settings from a configuration register such as a mode register to determine how many bank groups to select for burst per access transaction.

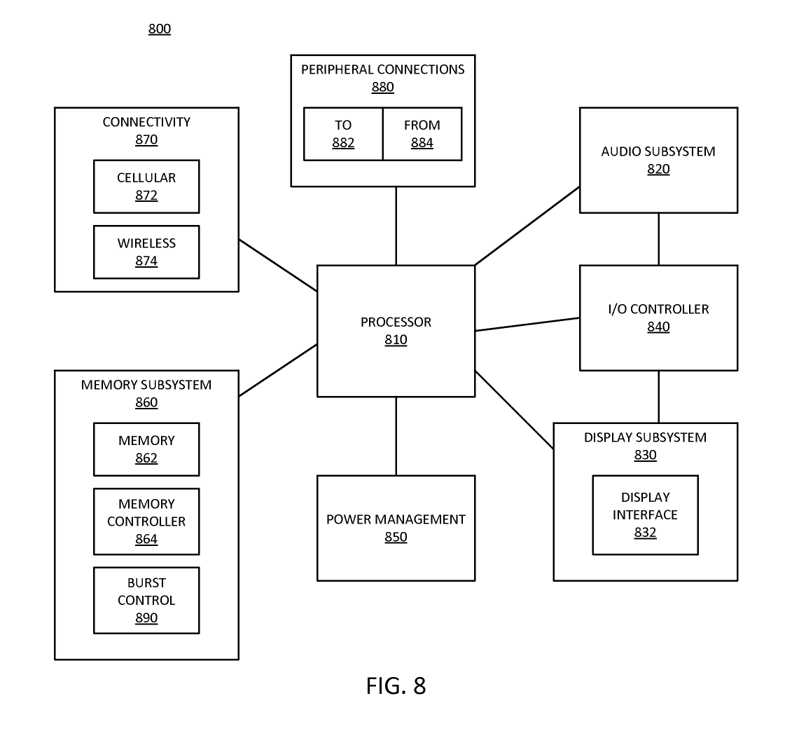

FIG. 8 is a block diagram of an embodiment of a mobile device in which memory device internal burst control can be implemented. Device 800 represents a mobile computing device, such as a computing tablet, a mobile phone or smartphone, a wireless-enabled e-reader, wearable computing device, or other mobile device. It will be understood that certain of the components are shown generally, and not all components of such a device are shown in device 800.

Device 800 includes processor 810, which performs the primary processing operations of device 800. Processor 810 can include one or more physical devices, such as microprocessors, application processors, microcontrollers, programmable logic devices, or other processing means. The processing operations performed by processor 810 include the execution of an operating platform or operating system on which applications and/or device functions are executed. The processing operations include operations related to I/O (input/output) with a human user or with other devices, operations related to power management, and/or operations related to connecting device 800 to another device. The processing operations can also include operations related to audio I/O and/or display I/O.

In one embodiment, device 800 includes audio subsystem 820, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into device 800, or connected to device 800. In one embodiment, a user interacts with device 800 by providing audio commands that are received and processed by processor 810.

Display subsystem 830 represents hardware (e.g., display devices) and software (e.g., drivers) components that provide a visual and/or tactile display for a user to interact with the computing device. Display subsystem 830 includes display interface 832, which includes the particular screen or hardware device used to provide a display to a user. In one embodiment, display interface 832 includes logic separate from processor 810 to perform at least some processing related to the display. In one embodiment, display subsystem 830 includes a touchscreen device that provides both output and input to a user. In one embodiment, display subsystem 830 includes a high definition (HD) display that provides an output to a user. High definition can refer to a display having a pixel density of approximately 100 PPI (pixels per inch) or greater, and can include formats such as full HD (e.g., 1080p), retina displays, 4K (ultra high definition or UHD), or others.

I/O controller 840 represents hardware devices and software components related to interaction with a user. I/O controller 840 can operate to manage hardware that is part of audio subsystem 820 and/or display subsystem 830. Additionally, I/O controller 840 illustrates a connection point for additional devices that connect to device 800 through which a user might interact with the system. For example, devices that can be attached to device 800 might include microphone devices, speaker or stereo systems, video systems or other display device, keyboard or keypad devices, or other I/O devices for use with specific applications such as card readers or other devices.

As mentioned above, I/O controller 840 can interact with audio subsystem 820 and/or display subsystem 830. For example, input through a microphone or other audio device can provide input or commands for one or more applications or functions of device 800. Additionally, audio output can be provided instead of or in addition to display output. In another example, if display subsystem includes a touchscreen, the display device also acts as an input device, which can be at least partially managed by I/O controller 840. There can also be additional buttons or switches on device 800 to provide I/O functions managed by I/O controller 840.

In one embodiment, I/O controller 840 manages devices such as accelerometers, cameras, light sensors or other environmental sensors, gyroscopes, global positioning system (GPS), or other hardware that can be included in device 800. The input can be part of direct user interaction, as well as providing environmental input to the system to influence its operations (such as filtering for noise, adjusting displays for brightness detection, applying a flash for a camera, or other features). In one embodiment, device 800 includes power management 850 that manages battery power usage, charging of the battery, and features related to power saving operation.

Memory subsystem 860 includes memory device(s) 862 for storing information in device 800. Memory subsystem 860 can include nonvolatile (state does not change if power to the memory device is interrupted) and/or volatile (state is indeterminate if power to the memory device is interrupted) memory devices. Memory 860 can store application data, user data, music, photos, documents, or other data, as well as system data (whether long-term or temporary) related to the execution of the applications and functions of system 800. In one embodiment, memory subsystem 860 includes memory controller 864 (which could also be considered part of the control of system 800, and could potentially be considered part of processor 810). Memory controller 864 includes a scheduler to generate and issue commands to memory device 862.

Connectivity 870 includes hardware devices (e.g., wireless and/or wired connectors and communication hardware) and software components (e.g., drivers, protocol stacks) to enable device 800 to communicate with external devices. The external device could be separate devices, such as other computing devices, wireless access points or base stations, as well as peripherals such as headsets, printers, or other devices.

Connectivity 870 can include multiple different types of connectivity. To generalize, device 800 is illustrated with cellular connectivity 872 and wireless connectivity 874. Cellular connectivity 872 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 874 refers to wireless connectivity that is not cellular, and can include personal area networks (such as Bluetooth), local area networks (such as WiFi), and/or wide area networks (such as WiMax), or other wireless communication. Wireless communication refers to transfer of data through the use of modulated electromagnetic radiation through a non-solid medium. Wired communication occurs through a solid communication medium.

Peripheral connections 880 include hardware interfaces and connectors, as well as software components (e.g., drivers, protocol stacks) to make peripheral connections. It will be understood that device 800 could both be a peripheral device (“to” 882) to other computing devices, as well as have peripheral devices (“from” 884) connected to it. Device 800 commonly has a “docking” connector to connect to other computing devices for purposes such as managing (e.g., downloading and/or uploading, changing, synchronizing) content on device 800. Additionally, a docking connector can allow device 800 to connect to certain peripherals that allow device 800 to control content output, for example, to audiovisual or other systems.

In addition to a proprietary docking connector or other proprietary connection hardware, device 800 can make peripheral connections 880 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other type.

In one embodiment, system 800 includes burst control 890, which can be logic within memory 862 of memory subsystem 860. Burst control 890 enables memory 862 to generate multiple internal operations in response to a single memory access command transaction from memory controller 864, in accordance with any embodiment described herein. Thus, memory 862 can internally perform operations to extend a burst length of I/O with memory controller 864 without the memory controller needing to send multiple latching commands. In one embodiment, burst control 890 can include an internal bank group counter, and logic to control the sequence of the internal operations. In one embodiment burst control 890 accesses settings from a configuration register such as a mode register to determine how many bank groups to select for burst per access transaction.

In one aspect, a method for memory device access includes: dynamically selecting a number of bank groups to operate in a burst sequence, from among multiple independent bank groups that are separately addressable, where each selected bank group is to operate on a command received from an associated memory controller; receiving a single access command from the associated memory controller; and generating multiple internal operations within the memory device to cause all selected bank groups to execute the access command.

In one embodiment, selecting the number of bank groups comprises selecting the number of bank groups in response to a setting in a mode register of the memory device. In one embodiment, selecting the number of bank groups comprises selecting the number of bank groups in response to an on-the-fly command from the memory controller indicating a desired burst length. In one embodiment, selecting the number of bank groups comprises selecting from among multiple programmable burst lengths. In one embodiment, receiving the single access command comprises receiving a single Activate and CAS (column address select) sequence; and wherein generating the multiple internal operations comprises applying the Activate and CAS sequence to all selected bank groups. In one embodiment, the Activate and CAS sequence comprise a Read command. In one embodiment, the Activate and CAS sequence comprise a Write command. In one embodiment, generating the multiple internal operations further comprises monitoring bank group operations via a bank group counter internal to the memory device. In one embodiment, generating the multiple internal operations comprises performing the operations in order of sequential bank group address. In one embodiment, generating the multiple internal operations comprises performing the operations in non-sequential order with interleaved bank group addresses.

In one aspect, a memory device in a memory subsystem includes: multiple banks of memory, wherein bank separately addressable from other banks; I/O (input/output) hardware configured to receive an access command, the access command to be generated by an associated memory controller; and control logic within the memory device to dynamically select a number of banks to operate in a burst sequence, and generate multiple internal operations within the memory device in response to the access command to cause all selected banks to execute the access command.

In one embodiment, the multiple banks of memory are organized as independent bank groups each including one or more banks, wherein all banks in a bank group are addressed together. In one embodiment, further comprising a mode register to store settings that control operation of the memory device, wherein the control logic is to select the number of banks including reading a burst mode setting in the mode register, and selecting the number of banks in response to the burst mode setting. In one embodiment, the control logic is to select the number of banks in response to an on-the-fly command from the memory controller indicating a desired burst length. In one embodiment, the control logic is to select the number of bank groups based on among multiple programmable burst lengths. In one embodiment, the I/O hardware is to receive a single Activate and CAS (column address select) sequence; and wherein the control logic is to apply the Activate and CAS sequence to all selected banks. In one embodiment, the Activate and CAS sequence comprise a Read command. In one embodiment, the Activate and CAS sequence comprise a Write command. In one embodiment, further comprising a counter internal to the memory device, and wherein the control logic is to monitor bank operations via the counter, including tracking sequencing of operations for the banks. In one embodiment, the control logic is to generate the multiple internal operations in order of sequential bank group address. In one embodiment, the control logic is to generate the multiple internal operations in non-sequential order with interleaved bank group addresses.

In one aspect, an electronic device with a memory subsystem includes: a memory controller; a memory device to interface with the memory controller, the memory device including multiple bank groups, each separately addressable; I/O (input/output) hardware to receive an access command from the memory controller; control logic within the memory device to dynamically select a number of bank groups to operate in a burst sequence, and generate multiple internal operations within the memory device in response to the access command to cause all selected bank groups to execute the access command; and a touchscreen display coupled to generate an interactive display based on data accessed from the memory device. The electronic device can include a memory device in accordance with any embodiment of the memory device.

In one aspect, an article of manufacture comprising a computer readable storage medium having content stored thereon, which when accessed causes a device to perform operations for memory device access, including: dynamically selecting a number of bank groups to operate in a burst sequence, from among multiple independent bank groups that are separately addressable, where each selected bank group is to operate on a command received from an associated memory controller; receiving a single access command from the associated memory controller; and generating multiple internal operations within the memory device to cause all selected bank groups to execute the access command. The article of manufacture can include content for performing operations in accordance with any embodiment of the method.

In one aspect, an apparatus for memory device access includes means for dynamically selecting a number of bank groups to operate in a burst sequence, from among multiple independent bank groups that are separately addressable, where each selected bank group is to operate on a command received from an associated memory controller; means for receiving a single access command from the associated memory controller; and means for generating multiple internal operations within the memory device to cause all selected bank groups to execute the access command. The apparatus can include means for performing operations in accordance with any embodiment of the method.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to the disclosed embodiments and implementations of the invention without departing from their scope. Therefore, the illustrations and examples herein should be construed in an illustrative, and not a restrictive sense. The scope of the invention should be measured solely by reference to the claims that follow.

What is claimed is:

1. A method for memory device access, comprising:
dynamically selecting a number of bank groups to operate in a burst sequence, from among multiple independent bank groups that are separately addressable, where each selected bank group is to operate on a command received from an associated memory controller;
receiving a single access command from the associated memory controller; and
generating multiple internal operations within the memory device to cause all selected bank groups to execute the access command.

2. The method of claim 1, wherein selecting the number of bank groups comprises selecting the number of bank groups in response to a setting in a mode register of the memory device.

3. The method of claim 1, wherein selecting the number of bank groups comprises selecting the number of bank groups in response to an on-the-fly command from the memory controller indicating a desired burst length.

4. The method of claim 1, wherein selecting the number of bank groups comprises selecting from among multiple programmable burst lengths.

5. The method of claim 1, wherein receiving the single access command comprises receiving a single Activate and CAS (column address select) sequence; and wherein generating the multiple internal operations comprises applying the Activate and CAS sequence to all selected bank groups.

6. The method of claim 5, wherein the Activate and CAS sequence comprise a Read command.

7. The method of claim 5, wherein the Activate and CAS sequence comprise a Write command.

8. The method of claim 1, wherein generating the multiple internal operations further comprises monitoring bank group operations via a bank group counter internal to the memory device.

9. The method of claim 8, wherein generating the multiple internal operations comprises performing the operations in order of sequential bank group address.

10. The method of claim 8, wherein generating the multiple internal operations comprises performing the operations in non-sequential order with interleaved bank group addresses.

11. A memory device in a memory subsystem, comprising:
multiple banks of memory, wherein bank separately addressable from other banks;
I/O (input/output) hardware configured to receive an access command, the access command to be generated by an associated memory controller; and
control logic within the memory device to dynamically select a number of banks to operate in a burst sequence, and generate multiple internal operations within the memory device in response to the access command to cause all selected banks to execute the access command.

12. The memory device of claim 11, wherein the multiple banks of memory are organized as independent bank groups each including one or more banks, wherein all banks in a bank group are addressed together.

13. The memory device of claim 11, further comprising a mode register to store settings that control operation of the memory device, wherein the control logic is to select the number of banks including reading a burst mode setting in the mode register, and selecting the number of banks in response to the burst mode setting.

14. The memory device of claim 11, wherein the control logic is to select the number of banks in response to an on-the-fly command from the memory controller indicating a desired burst length.

15. The memory device of claim 11, wherein the I/O hardware is to receive a single Activate and CAS (column address select) sequence; and wherein the control logic is to apply the Activate and CAS sequence to all selected banks.

16. The memory device of claim 11, further comprising a counter internal to the memory device, and wherein the control logic is to monitor bank operations via the counter, including tracking sequencing of operations for the banks.

17. An electronic device with a memory subsystem, comprising:
a memory controller;
a memory device to interface with the memory controller, the memory device including multiple bank groups, each separately addressable;
I/O (input/output) hardware to receive an access command from the memory controller;
control logic within the memory device to dynamically select a number of bank groups to operate in a burst sequence, and generate multiple internal operations within the memory device in response to the access command to cause all selected bank groups to execute the access command; and
a touchscreen display coupled to generate an interactive display based on data accessed from the memory device.

18. The electronic device of claim 17, the memory device further including a mode register to store settings that control operation of the memory device, wherein the control logic is to select the number of bank groups including reading a burst mode setting in the mode register, and selecting the number of bank groups in response to the burst mode setting.

19. The electronic device of claim 17, wherein the I/O hardware is to receive a single Activate and CAS (column address select) sequence from the memory controller; and wherein the control logic is to apply the Activate and CAS sequence to all selected bank groups.

20. The electronic device of claim 17, the memory device further including an internal counter, wherein the control logic is to monitor bank group operations via the counter, including tracking sequencing of operations for the bank groups.
